(19) United States
(12) Patent Application Publication
(10) Pub. No.: US 2025/0280614 A1
(43) Pub. Date: Sep. 4, 2025

(54) IMAGE SENSING DEVICE

(71) Applicant: SK hynix Inc., Icheon-si (KR)

(72) Inventor: Seung Hoon SA, Icheon-si (KR)

(21) Appl. No.: 19/051,163

(22) Filed: Feb. 11, 2025

(30) Foreign Application Priority Data
Feb. 29, 2024 (KR) 10-2024-0030254

(51) Int. Cl. H10F 39/00

(52) U.S. Cl. CPC H10F 39/80373; H10F 39/807

(57) ABSTRACT

The image sensing device includes a photoelectric conversion region including impurities of a first type in a semiconductor substrate; a well region including impurities of a second type opposite to the first type and disposed over the photoelectric conversion region in the semiconductor substrate, the well region being in contact with the photoelectric conversion region in the semiconductor substrate; a floating diffusion region located in the well region; and a transfer gate disposed in the semiconductor substrate and coupled between the photoelectric conversion region and the floating diffusion region to transmit photocharges from the photoelectric conversion region to the floating diffusion region. The transfer gate includes a recess gate formed in a recess etched into the semiconductor substrate and a gate insulation layer disposed between the recess gate and the semiconductor substrate. The gate insulation layer has a varying thickness based on a distance to the floating diffusion region.

### PRIORITY CLAIM AND CROSS-REFERENCE TO RELATED APPLICATION

This patent document claims the priority and benefits of Korean patent application No. 10-2024-0030254, filed on Feb. 29, 2024, which is incorporated by reference in its entirety as part of the disclosure of this patent document.

### TECHNICAL FIELD

The technology and implementations disclosed in this patent document generally relate to an image sensing device.

### BACKGROUND

An image sensor is used in electronic devices to convert optical images into electrical signals. With the recent development of automotive, medical, computer and communication industries, the demand for highly integrated, higher-performance image sensors has been rapidly increasing in various electronic devices such as digital cameras, camcorders, personal communication systems (PCSs), video game consoles, surveillance cameras, medical micro-cameras, robots, etc.

### SUMMARY

Various embodiments of the disclosed technology relate to an image sensing device that improves operation characteristics thereof by improving a structure of a transfer transistor.

In accordance with an embodiment of the disclosed technology, an image sensing device may include a semiconductor substrate; a photoelectric conversion region including impurities of a first type in the semiconductor substrate and configured to generate photocharges through conversion of incident light; a well region including impurities of a second type opposite to the first type and disposed over the photoelectric conversion region in the semiconductor substrate, the well region being in contact with the photoelectric conversion region in the semiconductor substrate; a floating diffusion region located in the well region and configured to store the photocharges; and a transfer gate disposed in the semiconductor substrate and coupled between the photoelectric conversion region and the floating diffusion region to transmit photocharges generated by the photoelectric conversion region to the floating diffusion region. The transfer gate may include a recess gate formed in a recess etched into the semiconductor substrate and a gate insulation layer disposed between the recess gate and the semiconductor substrate. The gate insulation layer may have a varying thickness based on a distance to the floating diffusion region.

In accordance with another embodiment of the disclosed technology, an image sensing device may include a semiconductor substrate configured to include a first surface and a second surface facing or opposite to the first surface; a photoelectric conversion region disposed in the semiconductor substrate and configured to generate photocharges through a conversion of incident light; a recess formed in the semiconductor substrate and extending from the second surface toward the photoelectric conversion region; a gate insulation layer disposed along a side surface and a bottom surface of the recess; a recess gate disposed over the gate insulation layer and configured to located in the recess; and a first impurity region configured to contact the second surface and spaced apart from the recess, the first impurity region including impurities of a first type. The gate insulation layer located at the side surface of the recess may have different thicknesses depending on a distance to the first impurity region.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a block diagram illustrating an example of an image sensing device according to embodiments of the disclosed technology.

FIG. 2 is a plan view illustrating an example of a planar structure of one pixel block of a pixel array shown in FIG. 1 according to embodiments of the disclosed technology.

FIG. 3A is an enlarged plan view illustrating an example of a region where a transfer gate and a floating diffusion region shown in FIG. 2 are formed according to embodiments of the disclosed technology.

FIG. 3B is a cross-sectional view illustrating an example of a pixel block taken along the line A-A′ shown in FIG. 3A according to embodiments of the disclosed technology.

FIG. 4 is a comparative example of a schematic diagram showing a pixel block including a gate insulation layer having an overall uniform thickness and movements of photocharges (electrons).

FIG. 5A is a plan view illustrating an example of a planar structure of a pixel block (PX_R) according to another embodiment of the disclosed technology.

FIG. 5B is an enlarged plan view illustrating an example of a region where a transfer gate and a floating diffusion region shown in FIG. 5A are formed according to another embodiment of the disclosed technology.

### DETAILED DESCRIPTION

This patent document provides implementations and examples of an image sensing device that may be used to substantially address one or more technical or engineering issues and mitigate limitations or disadvantages encountered in some other image sensing devices. Some implementations of the disclosed technology suggest examples of an image sensing device that improves operation characteristics thereof by improving a structure of a transfer transistor. In recognition of the issues above, the disclosed technology provides various implementations of the image sensing device that can improve operation characteristics thereof. In particular, the disclosed technology provides various implementations of the image sensing device that can improve transfer efficiency of a transfer transistor.

Reference will now be made in detail to certain embodiments, examples of which are illustrated in the accompanying drawings. Wherever possible, the same reference numbers will be used throughout the drawings to refer to the same or similar parts. In the following description, a detailed description of related known configurations or functions incorporated herein will be omitted to avoid obscuring the subject matter.

Hereinafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

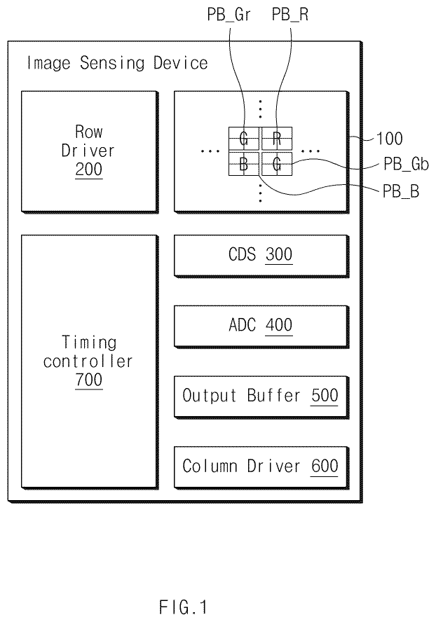

FIG. 1 is a block diagram illustrating an example of an image sensing device according to embodiments of the disclosed technology.

Referring to FIG. 1, the image sensing device may include a pixel array 100, a row driver 200, a correlated double sampler (CDS) 300, an analog-to-digital converter (ADC) 400, an output buffer 500, a column driver 600, and a timing controller 700. The components of the image sensing device illustrated in FIG. 1 are discussed by way of example only, and this patent document encompasses numerous other changes, substitutions, variations, alterations, and modifications. In this patent document, the word “pixel” can be used to indicate an image sensing pixel that is structured to detect incident light to generate electrical signals carrying images in the incident light.

The pixel array 100 may include a plurality of pixel blocks (PB_R, PB_Gr, PB_Gb, PB_B) consecutively arranged in rows and columns. The pixel blocks (PB_R, PB_Gr, PB_Gb, PB_B) may be arranged adjacent to each other in a (2×2) matrix structure in a Bayer pattern. The (2×2) matrix structure is the example only and the pixel blocks can be arranged in a different configuration from the (2×2) matrix structure. Each of the pixel blocks (PB_R, PB_Gr, PB_Gb, PB_B) may include a structure in which a plurality of unit pixels shares a floating diffusion region and pixel transistors. Each unit pixel may include a photoelectric conversion region (e.g., a photodiode PD) for photoelectrically converting incident light to generate and accumulate photocharges, and a transfer gate for transmitting photocharges generated by the photoelectric conversion region to a floating diffusion region according to a transfer signal. The transfer gate may include a recess gate buried in a semiconductor substrate. The floating diffusion regions respectively included in the pixel blocks (PB_R, PB_Gr, PB_Gb, PB_B) may be electrically connected to each other through a conductive line. Adjacent unit pixels may be isolated from each other by a trench-type pixel isolation layer.

The pixel array 100 may receive driving signals (for example, a row selection signal, a reset signal, a transmission (or transfer) signal, etc.) from the row driver 200. Upon receiving the driving signals, the unit pixels may be activated to perform the operations corresponding to the row selection signal, the reset signal, and the transfer signal.

The row driver 200 may activate the pixel array 100 to perform certain operations on the unit pixels in the corresponding row based on control signals provided by controller circuitry such as the timing controller 700. In some implementations, the row driver 200 may select one or more pixel groups arranged in one or more rows of the pixel array 100. The row driver 200 may generate a row selection signal to select one or more rows from among the plurality of rows. The row driver 200 may sequentially enable the reset signal and the transfer signal for the unit pixels arranged in the selected row. The pixel signals generated by the unit pixels arranged in the selected row may be output to the correlated double sampler (CDS) 300.

The correlated double sampler (CDS) 300 may remove undesired offset values of the unit pixels using correlated double sampling. In one example, the correlated double sampler (CDS) 300 may remove the undesired offset values of the unit pixels by comparing output voltages of pixel signals (of the unit pixels) obtained before and after photocharges generated by incident light are accumulated in the sensing node (i.e., a floating diffusion (FD) node). As a result, the CDS 300 may obtain a pixel signal generated only by the incident light without causing noise. In some implementations, upon receiving a clock signal from the timing controller 700, the CDS 300 may sequentially sample and hold voltage levels of the reference signal and the pixel signal, which are provided to each of a plurality of column lines from the pixel array 100. That is, the CDS 300 may sample and hold the voltage levels of the reference signal and the pixel signal which correspond to each of the columns of the pixel array 100. In some implementations, the CDS 300 may transfer the reference signal and the pixel signal of each of the columns as a correlate double sampling (CDS) signal to the ADC 400 based on control signals from the timing controller 700.

The ADC 400 is used to convert analog CDS signals received from the CDS 300 into digital signals. In some implementations, the ADC 400 may be implemented as a ramp-compare type ADC. The analog-to-digital converter (ADC) 400 may compare a ramp signal received from the timing controller 700 with the CDS signal received from the CDS 300, and may thus output a comparison signal indicating the result of comparison between the ramp signal and the CDS signal. The analog-to-digital converter (ADC) 400 may count a level transition time of the comparison signal in response to the ramp signal received from the timing controller 700, and may output a count value indicating the counted level transition time to the output buffer 500.

The output buffer 500 may temporarily store column-based image data provided from the ADC 400 based on control signals of the timing controller 700. The image data received from the ADC 400 may be temporarily stored in the output buffer 500 based on control signals of the timing controller 700. The output buffer 500 may provide an interface to compensate for data rate differences or transmission rate differences between the image sensing device and other devices.

The column driver 600 may select a column of the output buffer 500 upon receiving a control signal from the timing controller 700, and sequentially output the image data, which are temporarily stored in the selected column of the output buffer 500. In some implementations, upon receiving an address signal from the timing controller 700, the column driver 600 may generate a column selection signal based on the address signal, may select a column of the output buffer 500 using the column selection signal, and may control the image data received from the selected column of the output buffer 500 to be output as an output signal.

The timing controller 700 may generate signals for controlling operations of the row driver 200, the ADC 400, the output buffer 500 and the column driver 600. The timing controller 700 may provide the row driver 200, the column driver 600, the ADC 400, and the output buffer 500 with a clock signal required for the operations of the respective components of the image sensing device, a control signal for timing control, and address signals for selecting a row or column. In some implementations, the timing controller 700 may include a logic control circuit, a phase lock loop (PLL) circuit, a timing control circuit, a communication interface circuit and others.

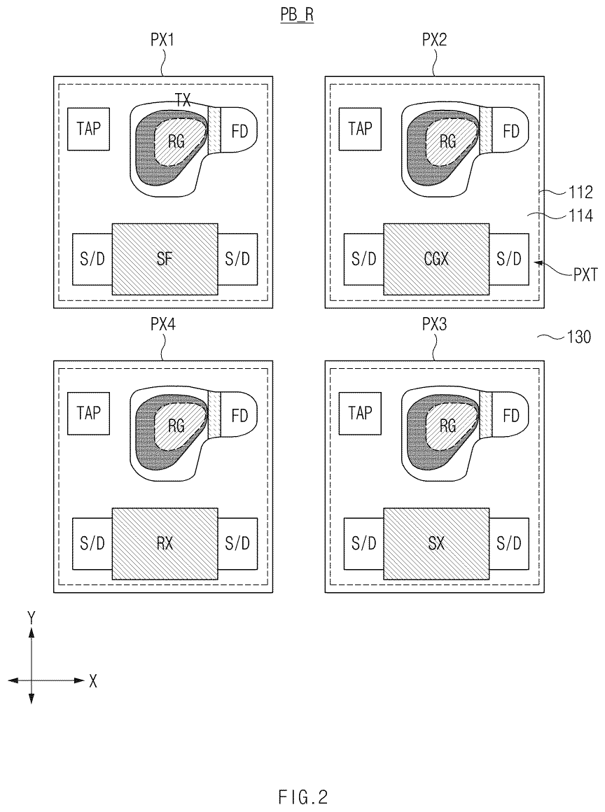

FIG. 2 is a plan view illustrating an example of a planar structure of one pixel block (PB_R) of the pixel array 100 shown in FIG. 1 according to embodiments of the disclosed technology.

Since a plurality of pixel blocks (PB_R, PB_Gr, PB_Gb, PB_B) has the same structure except for a difference in color between color filters, only a pixel block (PB_R) will hereinafter be described as a representative pixel block for convenience of description and better understanding of the disclosed technology.

Referring to FIG. 2, the pixel block (PB_R) may include four unit pixels (PX1˜PX4) arranged adjacent to each other in a (2×2) matrix including two columns and two rows. The unit pixels (PX1˜PX4) may be disposed adjacent to each other in a first direction (e.g., an X-axis direction) and in a second direction (e.g., a Y-axis direction) perpendicular to the first direction. For example, the pixel block (PB_R) may include unit pixels (PX1˜PX4) arranged in a (2×2) matrix structure including two rows and two columns. As mentioned above, the (2×2) matrix structure is the example only and the pixel blocks can be arranged in a different configuration from the (2×2) matrix structure.

In some implementations, the unit pixels (PX1˜PX4) may be included as fully isolated pixels that are physically and completely isolated from each other by a pixel isolation structure 130. For example, each of the unit pixels (PX1˜PX4) may include a photoelectric conversion region 112, a floating diffusion region (FD), pixel transistors (PXT), and a well-tap region (TAP). At this time, the floating diffusion regions (FD) of the unit pixels (PX1˜PX4) may be electrically connected to each other through a conductive line to form one common floating diffusion node. The unit pixels (PX1˜PX4) may be formed in a Back Side Illumination (BSI) structure.

Each of the unit pixels (PX1˜PX4) may include a transfer transistor (TX), one pixel transistor (PXT), and a well-tap region (TAP). The transfer transistor (TX) may transmit photocharges

generated by the photoelectric conversion region 112 of the corresponding unit pixel (PX1˜PX4) to the floating diffusion region (FD) based on the transfer signal. The transfer transistor (TX) may be a transistor in which the photoelectric conversion region 112 and the floating diffusion region (FD) are used as source/drain regions. A gate (i.e., transfer gate) of the transfer transistor (TX) may include a recess gate, at least a portion of which is buried in a substrate to form a channel in a vertical direction.

The pixel transistor (PXT) may include a gate and source/drain regions (S/D) located at two sides of the gate. Each pixel transistor (PXT) may be or include at least one of a source follower transistor (SF), a conversion gain transistor (CGX), a selection transistor (SX), or a reset transistor (RX). The source follower transistor (SF) may generate a pixel signal corresponding to the magnitude of a voltage of a common floating diffusion node. The conversion gain transistor (CGX) may adjust capacitance of the common floating diffusion node. The selection transistor (SX) may output a pixel signal output from the source follower transistor (SF) to a column line in response to a row selection signal. The reset transistor (RX) may initialize the common floating diffusion node in response to a reset signal. The conversion gain transistor (CGX) can also be used as a dummy transistor.

Electrical connection between devices (or elements) belonging to different unit pixels may be achieved through conductive lines (e.g., metal lines) formed over the substrate.

The well-tap region (TAP) may apply a bias voltage to a well region within the semiconductor substrate 110. For example, by providing the bias voltage to the well region, the well-tap region (TAP) helps to maintain such voltage level within the well. The well-tap region (TAP) may be located adjacent to the transfer gate in the first direction within each of the unit pixels (PX1˜PX4).

Adjacent unit pixels (PX1˜PX4) may be isolated from each other by the pixel isolation structure 130. The transfer transistor (TX), the pixel transistor (PXT), and the well-tap region (TAP) may be isolated from each other by a device isolation structure 114 within each of the unit pixels (PX1˜PX4).

Each of the device isolation structure 114 and the pixel isolation structure 130 may include a trench-type isolation structure in which an insulation material is buried in a trench formed by etching the substrate. For example, the device isolation structure 114 may include a shallow trench isolation (STI) structure, and the pixel isolation structure 130 may include a deep trench isolation (DTI) structure.

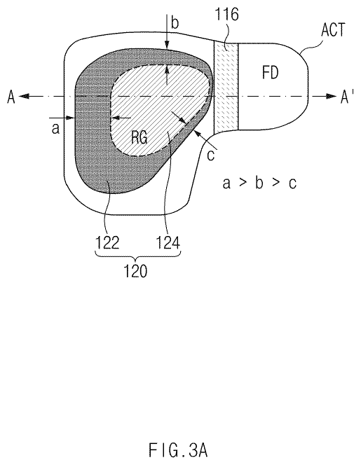

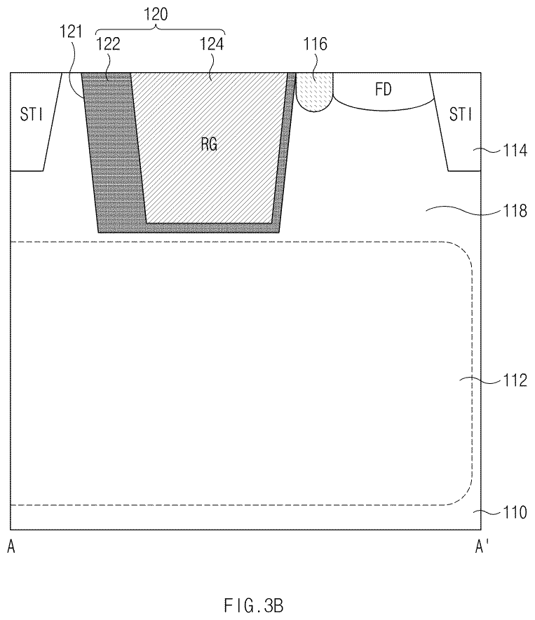

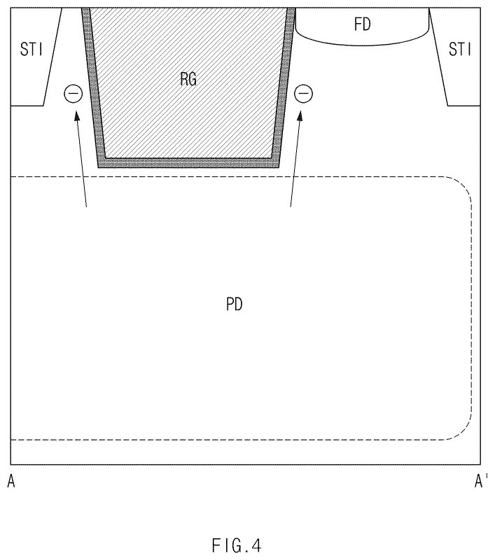

FIG. 3A is an enlarged plan view illustrating an example of a region where the transfer gate and the floating diffusion region shown in FIG. 2 are formed according to embodiments of the disclosed technology. FIG. 3B is a cross-sectional view illustrating an example of a pixel block taken along the line A-A′ shown in FIG. 3A according to embodiments of the disclosed technology. FIG. 4 is a comparative example of the embodiment of FIG. 3B and is a schematic diagram illustrating the movement of photocharges (electrons) when the gate insulation layer is formed with the same thickness.

Referring to FIGS. 3A, 3B and 4, a semiconductor substrate 110 may include a first surface and a second surface facing or opposite to the first surface. In the example, the first surface may be a surface upon which light is incident, and may be used as a bottom surface of FIG. 3B. The second surface may be a surface in which transistors are formed, and may be used as a top surface of FIG. 3B.

The photoelectric conversion region 112 may include impurities of a first type (e.g., N-type impurities), and may generate photocharges through photoelectric conversion of incident light and accumulate the photocharges. One photoelectric conversion region 112 may be formed for each unit pixel (PX1˜PX4), and adjacent photoelectric conversion regions 112 may be isolated from each other by the pixel isolation structure (130 of FIG. 2).

A well region 118 that forms a PN junction with the photoelectric conversion region 112 and forms a channel of transistors (TX, PXT) may be formed over the photoelectric conversion region 112 within the semiconductor substrate 110. The well region 118 may include impurities of a second type (e.g., P-type) opposite to the first type. A floating diffusion region (FD) and a FD isolation region 116 may be formed in the well region 118.

The floating diffusion region (FD) may be located in the well region 118 to contact the second surface of the semiconductor substrate 110, and may include first-type impurities. In the example, the floating diffusion region (FD) extends from the second surface of the semiconductor substrate 110 toward the first surface of the semiconductor substrate 110. The floating diffusion region (FD) may store photocharges generated by the photoelectric conversion region 112, and may be electrically connected to the gate of the source follower transistor (SF) within the pixel block (PB_R). The floating diffusion region (FD) may be isolated from the transfer gate 120 by the FD isolation region 116.

The device isolation structure 114 may be provided to isolate active regions from each other. Within each of the unit pixels (PX1˜PX4), the active region (ACT) in which the transfer transistor (TX) and the floating diffusion region (FD) are formed may be isolated from other active regions each including the well-tap region (TAP) and the pixel transistor (PXT) by the device isolation structure 114. In the example, the device isolation structure 114 may include a trench-type STI structure.

The transfer transistor (TX) may include a recess-type transfer gate 120. The recess-type transfer gate 120 may include a conductive material buried in a recess (i.e., a gate recess) 121 that is formed by etching the semiconductor substrate so that the conductive material in the recess forms a gate that is at least partially buried in the recess or a “recess gate.” The transfer gate 120 may form a channel in the well region 118 disposed between the photoelectric conversion region 112 and the floating diffusion region (FD) according to the transfer signal, and may transmit photocharges (electrons) generated by the photoelectric conversion region 112 to the floating diffusion region (FD). The transfer gate 120 may be formed in a triangular shape when viewed in a plane.

The transfer gate 120 may include a gate insulation layer 122 and a recess gate 124. The gate insulation layer 122 may include an insulation layer that is formed along the inner surface (i.e., inner side surface and bottom surface) of the gate recess 121 and surrounds the side and bottom surfaces of the recess gate 124. The gate insulation layer 122 may include an oxide layer. The recess gate 124 may be formed over the gate insulation layer 122 to fill the gate recess 121. The recess gate 124 may include polysilicon doped with impurities.

In some implementations, the gate insulation layer 122 may have a varying thickness instead of having an overall uniform thickness. For example, the gate insulation layer 122 may be formed to have a different thickness based on a distance to the floating diffusion region (FD) and/or the position of the transfer gate 120 with respect to the photoelectric conversion region 112 within each pixel (PX1˜PX4). For example, the gate insulation layer 122 located at the side surface of the transfer gate 120, which is relatively close to the floating diffusion region (FD), may be formed to be thin and may gradually increase as the distance to the floating diffusion region (FD) becomes further. Thus, the gate insulation layer 122 located at the other side surface of the transfer gate 120, which is relatively further from the floating diffusion region (FD), may be formed to be thick. In some implementations, the gate insulation layer 122 has a relatively smaller thickness at a region located to face a wide area of the photoelectric conversion region 112, as compared to other regions facing or opposite to the region.

FIG. 4 illustrates a comparative example of a schematic diagram showing a pixel block including a gate insulation layer having an overall uniform thickness and movements of photocharges (electrons). Referring to FIG. 4, the gate insulation layer has an overall uniform thickness on the side surfaces of the recess gate (RG) unlike the implementation as shown in FIG. 3B. In this case, when the transfer transistor is turned on, at the side surfaces of the recess gate (RG), a potential having an overall uniform magnitude is formed, so that a large amount of photocharges can move even toward a region that is relatively further from the floating diffusion region (FD), while the floating diffusion region (FD) is not formed in the region. For example, when the recess gate (RG) has two side surfaces, a first side surface adjacent to the floating diffusion region (FD) and a second, opposite side surface relatively further from the floating diffusion region (FD), a large amount of photocharges can move toward the second side surface and thus the amount of photocharges moving toward the first side surface is reduced. In this case, the large amount of photocharges may move to the floating diffusion region (FD) along a longer route without directly moving to the floating diffusion region (FD), resulting in reduction in transmission efficiency.

To address such reduction in transmission efficiency, some implementations of the disclosed technology provide a transfer gate including a gate insulation layer having a varying thickness. When the transfer gate 120 is turned on, the magnitude of a potential that is formed around the transfer gate 120 to move photocharges may vary depending on the thickness of the gate insulation layer 122. For example, in a region in which the gate insulation layer 122 has a relatively large thickness, the magnitude of the potential may be small, and in a region in which the gate insulation layer 122 has a relatively small thickness, the magnitude of the potential may be large. Therefore, as in the present embodiment, the region located relatively close to the floating diffusion region (FD) on the side surface of the transfer gate 120 is formed so that the gate insulation layer 122 becomes thinner, and the other region located further from the floating diffusion region (FD) is formed so that the gate insulation layer 122 becomes thicker. As a result, when the transfer gate 120 is turned on, much more photocharges can move through the region located relatively close to the floating diffusion region (FD).

In some implementations, when only a specific region adjacent to the floating diffusion region (FD) in the gate insulation layer 122 is formed to have a small thickness and other regions except for the specific region are formed to have the same thickness, a potential may be large only in the specific region so that the movement of photocharges can be restricted. As a result, as the electric field is concentrated into the corresponding region, there is a higher possibility that the gate insulation layer of the corresponding region will be broken or damaged.

In the present embodiment, when the thickness of the gate insulation layer 122 is gradually increased as the distance to the floating diffusion region (FD) increases, the movement of photocharges toward the floating diffusion region (FD) may be more effectively controlled, and it is possible to prevent the electric field from being concentrated in the specific region.

In some implementations, the gate insulation layers 122 have a different thickness even at the regions having similar distances from the floating diffusion region (FD) if the distances from the center of the photoelectric conversion region 112 to the regions are different. When certain side surfaces from among the side surfaces of the transfer gate 120 are formed so that the corresponding side surfaces have similar distances to the floating diffusion region (FD) but have different distances to the center of the photoelectric conversion region 112 in a pixel, the gate insulation layers 122 at the corresponding side surfaces are formed to be different in thickness from each other. For example, as shown in FIG. 3A, the side region “b” and the side region “c” of the gate insulation layer 122 may be located by similar distances from the floating diffusion region (FD). However, as shown in FIG. 2, when the transfer gate 120 is not located at the center of the photoelectric conversion region 112 and is biased to one side when viewed in a plane, a distance from the center of the photoelectric conversion region 112 to the side region “b” and a distance from the center of the photoelectric conversion region 112 to the side region “c” may be different. In this case, the gate insulation layer 122 of the side region “c” located relatively close to the center of the photoelectric conversion region 112 may be formed to have a smaller thickness than the thickness of the gate insulation layer 122 of the side region “b”.

In the gate insulation layer 122, the region disposed between the semiconductor substrate 110 and the bottom surface of the recess gate 124 may be formed to have an overall uniform thickness.

In the embodiment of FIG. 3A, the gate insulation layer 122 has a varying thickness in consideration of both the distance to the floating diffusion region (FD) and the position of the transfer gate with respect to the photoelectric conversion region 112. However, other implementations are also possible. For example, in some implementations, the gate insulation layer 122 may have a varying thickness based on only the distance to the floating diffusion region (FD). In some implementations, the gate insulation layer 122 may have a varying thickness based on only the position of the transfer gate with respect to the photoelectric conversion region 112.

The FD isolation region 116 may isolate the transfer gate 120 and the floating diffusion region (FD) from each other, and may thus prevent photocharges of the floating diffusion region (FD) from leaking toward the well region 118 by the transfer gate 120. For example, the transfer transistor (TX) is a transistor in which the photoelectric conversion region 112 and the floating diffusion region (FD) are used as source/drain regions. Therefore, when the transfer transistor (TX) is turned off, a gate induced drain leakage (GIDL) current flowing from the floating diffusion region (FD) to the well region 118 may occur in a region in which the transfer gate 120 and the floating diffusion region (FD) are in contact with each other. In the present embodiment, the FD isolation region 116, which is a low-concentration second-type impurity region, may be formed between the transfer gate 120 and the floating diffusion region (FD) so that the transfer gate 120 and the floating diffusion region (FD) are not in contact with each other. The FD isolation region 116 may be formed to have a lower concentration than the well region 118. For example, the FD isolation region 116 may be formed with a doping concentration ranging from 1E11/cm³ to 1E17/cm³.

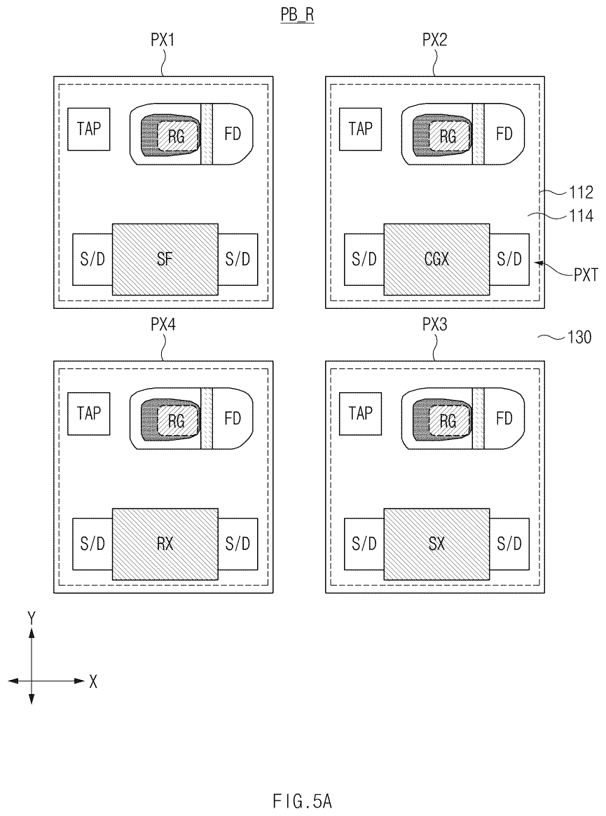

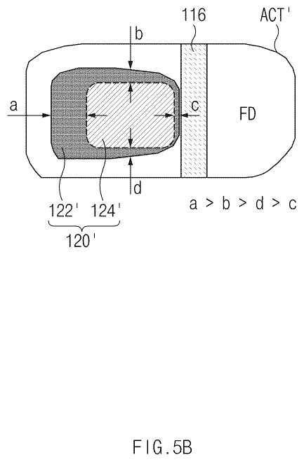

FIG. 5A is a plan view illustrating an example of a planar structure of a pixel block (PX_R) according to another embodiment of the disclosed technology. FIG. 5B is an enlarged plan view illustrating an example of a region where a transfer gate and a floating diffusion region shown in FIG. 5A are formed according to another embodiment of the disclosed technology.

Referring to FIGS. 5A and 5B, a transfer gate 120′ may be formed in a rectangular shape when viewed in a plane.

The transfer gate 120′ may include a gate insulation layer 122′ and a recess gate 124′.

In the same manner as the gate insulation layer 122 of FIGS. 3A and 3B described above, the gate insulation layer 122′ is not formed to have an overall uniform thickness, and may be formed to have a different thickness for each region according to both the distance to the floating diffusion region (FD) and the position of the transfer gate 120′ within each pixel (PX1˜PX4). For example, the gate insulation layer 122′ may be formed to have the smallest thickness in the side region “c” located to face the floating diffusion region (FD), and may be formed to have the largest thickness in the other side region “a” opposite to the side region “c”. In addition, the gate insulation layer 122′ of the side regions (“b” and “d”) disposed between the side region “a” and the side region “c” may have a smaller thickness than the side surface “a” while having a larger thickness than the side surface “c”, and the gate insulation layer 122′ may become thicker as the distance to the floating diffusion region (FD) increases. In addition, among the side region “b” and the side region “d”, the gate insulation layer 122′ of the side region “d” located relatively close to the center of the photoelectric conversion region 112 may be formed to have a smaller thickness than the gate insulation layer 122′ of the side region “b” opposite to the side region “d”.

As is apparent from the above description, the image sensing device based on some implementations of the disclosed technology can improve operation characteristics thereof.

In particular, the image sensing device based on some implementations of the disclosed technology can improve transfer efficiency of a transfer transistor.

The embodiments of the disclosed technology may provide a variety of effects capable of being directly or indirectly recognized through the above-mentioned patent document.

Although a number of illustrative embodiments have been described, it should be understood that various modifications or enhancements of the disclosed embodiments and other embodiments can be devised based on what is described and/or illustrated in this patent document.

What is claimed is:

1. An image sensing device, comprising:
a semiconductor substrate;
a photoelectric conversion region including impurities of a first type in the semiconductor substrate and configured to generate photocharges through a conversion of incident light;
a well region including impurities of a second type opposite to the first type and disposed over the photoelectric conversion region in the semiconductor substrate, the well region being in contact with the photoelectric conversion region in the semiconductor substrate;
a floating diffusion region located in the well region and configured to store the photocharges; and
a transfer gate disposed in the semiconductor substrate, and coupled between the photoelectric conversion region and the floating diffusion region to transmit photocharges generated by the photoelectric conversion region to the floating diffusion region,
wherein
the transfer gate includes a recess gate formed in a recess etched into the semiconductor substrate and a gate insulation layer disposed between the recess gate and the semiconductor substrate,
wherein
the gate insulation layer has a varying thickness based on a distance to the floating diffusion region.

2. The image sensing device according to claim 1, wherein a thickness of the gate insulation layer gradually increases as the distance to the floating diffusion region increases.

3. The image sensing device according to claim 2, wherein
a region of the gate insulation layer that is disposed between the semiconductor substrate and a bottom surface of the recess gate has a uniform thickness.

4. The image sensing device according to claim 1, wherein:
when viewed in a plane, the gate insulation layer has different thicknesses based on a position of the transfer gate with respect to the photoelectric conversion region.

5. The image sensing device according to claim 4, wherein the gate insulation layer includes a first side region and a second side region closer to a center of the photoelectric conversion region than the first side region,
the first side region has a larger thickness than a thickness of the second side region.

6. The image sensing device according to claim 1, further comprising:
a floating diffusion (FD) isolation region disposed between the transfer gate and the floating diffusion region and within the well region, the FD isolation region configured to prevent the transfer gate and the floating diffusion region from contacting each other.

7. The image sensing device according to claim 6, wherein:
the FD isolation region contains impurities of the second type having a lower concentration than a concentration of the impurities of the second type in the well region.

8. The image sensing device according to claim 1, further comprising:
a well-tap region configured to apply a bias voltage to the well region.

9. An image sensing device comprising:
a semiconductor substrate configured to include a first surface and a second surface facing or opposite to the first surface;
a photoelectric conversion region disposed in the semiconductor substrate and configured to generate photocharges through a conversion of incident light;
a recess formed in the semiconductor substrate and extending from the second surface toward the photoelectric conversion region;
a gate insulation layer disposed along a side surface and a bottom surface of the recess;
a recess gate disposed over the gate insulation layer and configured to locate in the recess; and
a first impurity region configured to contact the second surface and spaced apart from the recess, the first impurity region including impurities of a first type,
wherein
the gate insulation layer located at the side surface of the recess has different thicknesses depending on a distance to the first impurity region.

10. The image sensing device according to claim 9, wherein the gate insulation layer has a thickness that gradually increases as a distance to the first impurity region increases.

11. The image sensing device according to claim 10, wherein a region of the gate insulation layer that is disposed between the semiconductor substrate and a bottom surface of the recess gate has a uniform thickness.

12. The image sensing device according to claim 9, wherein:
when viewed in a plane, the gate insulation layer in a side region of the recess has different thicknesses based on a position of the recess with respect to the photoelectric conversion region.

13. The image sensing device according to claim 12, wherein the gate insulation layer includes a first side region and a second side region closer to a center of the photoelectric conversion region than the first side region, the first side region has a larger thickness than the thickness of a second side region.

14. The image sensing device according to claim 9, further comprising:
a second impurity region including impurities of a second type opposite to the first type of the impurities of the first impurity region and disposed between the first impurity region and the recess so as to contact the first impurity region.

15. The image sensing device according to claim 14, further comprising a well region disposed in the semiconductor substrate and including impurities of the second type.

16. The image sensing device according to claim 15, wherein:
the impurities of the second impurity region has a lower concentration than a concentration of the impurities of the well region.
